(19) United States
(12) Patent Application Publication
(10) Pub. No.: US 2024/0270567 A1
(43) Pub. Date: Aug. 15, 2024

(54) ACOUSTIC DEVICE AND MODULE INCLUDING THE SAME

(71) Applicant: Murata Manufacturing Co., Ltd., Nagaokakyo-shi (JP)

(72) Inventors: Hiroshi MATSUBARA, Nagaokakyo-shi (JP); Shinsuke IKEUCHI, Nagaokakyo-shi (JP); Ryosuke NIWA, Nagaokakyo-shi (JP); Takahiro ASADA, Nagaokakyo-shi (JP)

(21) Appl. No.: 18/632,485

(22) Filed: Apr. 11, 2024

Related U.S. Application Data
(63) Continuation of application No. PCT/JP2022/032599, filed on Aug. 30, 2022.

(30) Foreign Application Priority Data
Oct. 29, 2021 (JP) 2021-178068

(51) Int. Cl. B81C 1/00; B81B 7/00

(52) U.S. Cl. CPC B81C 1/00309; B81B 7/0061; B81B 2201/0257; B81B 2203/0353; B81B 2203/04; B81B 2207/096; B81C 2203/035

(57) ABSTRACT

An acoustic device includes a substrate including a first surface and a second surface facing a side opposite to the first surface, an opening, an acoustic MEMS element fixed to the first surface to cover the opening, an annular electrode surrounding the opening on the second surface, and a solder resist layer covering the second surface adjacently to the annular electrode on an outer side and an inner side of the annular electrode The solder resist layer includes a first cutaway portion to connect a first portion and a second portion to each other, the first portion being any portion in an edge of the annular electrode the second portion being any portion in an edge of the substrate.

### CROSS REFERENCE TO RELATED APPLICATIONS

This application claims the benefit of priority to Japanese Patent Application No. 2021-178068 filed on Oct. 29, 2021 and is a Continuation Application of PCT Application No. PCT/JP2022/032599 filed on Aug. 30, 2022. The entire contents of each application are hereby incorporated herein by reference.

### BACKGROUND OF THE INVENTION

### 1. Field of the Invention

The present invention relates to acoustic devices and modules including the same.

### 2. Description of the Related Art

Japanese National Patent Publication No. 2015-530030 describes a microphone assembly. On a lower surface of this microphone assembly, a portion called a port for entry of sound directed toward an MEMS device is provided. An annular electrode is provided to surround this port. In mounting such an acoustic device on a surface of some kind of mount substrate, solder mounting is carried out. Specifically, solder mounting is carried out by attachment of solder to the annular electrode provided on the lower surface of the acoustic device. Solder is arranged annularly and structured to surround the port.

### SUMMARY OF THE INVENTION

In solder mounting, gas may be generated from solder itself and bubbles caused by this gas may be confined in the solder and remain as voids in the solder. Gas may be generated not only from the solder itself but also from the mount substrate, in particular, from a connection electrode on the mount substrate, and such bubbles caused by gas may similarly remain as voids in solder. When a void caused for any reason is larger than a width of the annular electrode, solder which should annularly be continuous may become discontinuous. Specifically, an inner side and an outer side of the port communicate with each other and a sound leakage path may be produced. In order to avoid such a situation, the electrode should have a width equal to or larger than a certain width. An increase in the width of the annular electrode inevitably leads to an increase in the size of the substrate of the microphone assembly for arrangement of such an electrode. Consequently, a reduction in size as a whole is impeded.

Example embodiments of the present invention provide acoustic devices and modules in each of which a void in solder is less likely during solder mounting.

An acoustic device according to an example embodiment of the present invention includes a substrate including a first surface and a second surface that faces a side opposite to the first surface, the substrate being provided with an opening, an acoustic MEMS element fixed to the first surface to cover the opening, an annular electrode surrounding the opening on the second surface, and a solder resist layer covering the second surface adjacently to the annular electrode on an outer side and an inner side of the annular electrode, in which the solder resist layer includes a first cutaway portion to connect a first portion and a second portion to each other, the first portion being any portion in an edge of the annular electrode, the second portion being any portion in an edge of the substrate.

According to example embodiments of the present invention, even when an outgas is generated from solder attached to the annular electrode or the mount substrate in a reflow step during soldering, an outgas can escape through the first cutaway portion. Therefore, acoustic devices in each of which a void in solder is less likely can be provided.

The above and other elements, features, steps, characteristics and advantages of the present invention will become more apparent from the following detailed description of the example embodiments with reference to the attached drawings.

### BRIEF DESCRIPTION OF DRAWINGS

FIG. 1 is a perspective view of an acoustic device in a first example embodiment of the present invention.

FIG. 2 is an exploded view of the acoustic device in the first example embodiment of the present invention.

FIG. 3 is a cross-sectional view along the line III-III in FIG. 1.

FIG. 4 is a bottom view of the acoustic device in the first example embodiment of the present invention.

FIG. 5 is a cross-sectional view along the line V-V in FIG. 4.

FIG. 6 is a cross-sectional view along the line VI-VI in FIG. 4.

FIG. 7 is a cross-sectional view of a first cutaway portion and the vicinity thereof in a modification of the acoustic device in the first example embodiment of the present invention.

FIG. 8 is a bottom view of an acoustic device in a second example embodiment of the present invention.

FIG. 9 is a bottom view of an acoustic device in a third example embodiment of the present invention.

FIG. 10 is a cross-sectional view along the line X-X in FIG. 9.

FIG. 11 is a cross-sectional view along the line XI-XI in FIG. 9.

FIG. 12 is a bottom view of an acoustic device in a fourth example embodiment of the present invention.

FIG. 13 is a partial bottom view of a first modification of the acoustic device in the fourth example embodiment of the present invention.

FIG. 14 is a partial bottom view of a second modification of the acoustic device in the fourth example embodiment of the present invention.

FIG. 15 is a bottom view of an acoustic device in a fifth example embodiment of the present invention.

FIG. 16 shows a graph of relation between a frequency and a sound pressure.

FIG. 17 is a bottom view of an acoustic device in a sixth example embodiment of the present invention.

FIG. 18 is a cross-sectional view of a module in a seventh example embodiment of the present invention.

### DETAILED DESCRIPTION OF THE EXAMPLE EMBODIMENTS

A dimensional ratio shown in the drawings does not necessarily faithfully represent an actual dimensional ratio and a dimensional ratio may be exaggerated for the sake of convenience of description. A concept up or upper or down or lower mentioned in the description below does not mean absolute up or upper or down or lower but may mean relative up or upper or down or lower in terms of a shown position.

“MEMS” herein is an abbreviation of micro electro mechanical systems. An “acoustic MEMS element” is a collective denotation of an MEMS microphone, a piezoelectric micro-machined ultrasonic transducer (pMUT), a capacitive micro-machined ultrasonic transducer (cMUT), an MEMS speaker, and the like.

### First Example Embodiment

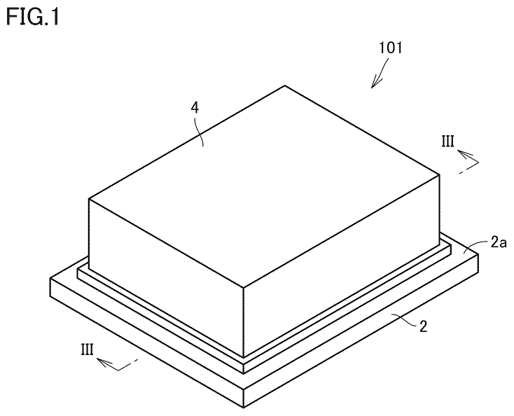

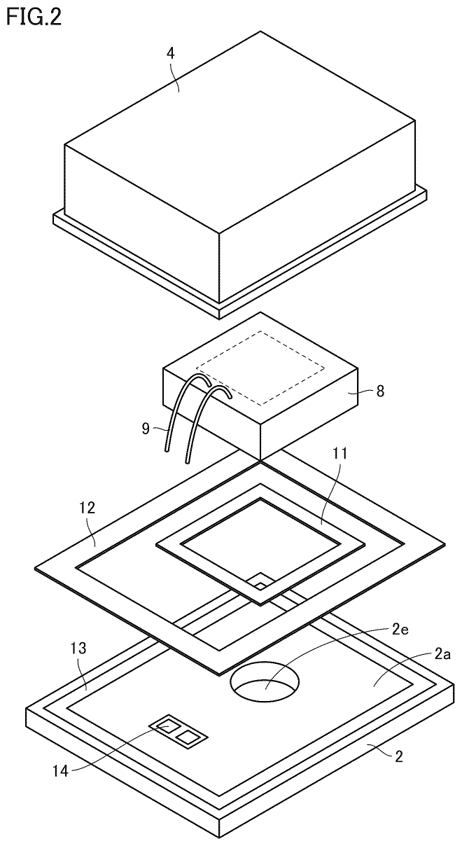

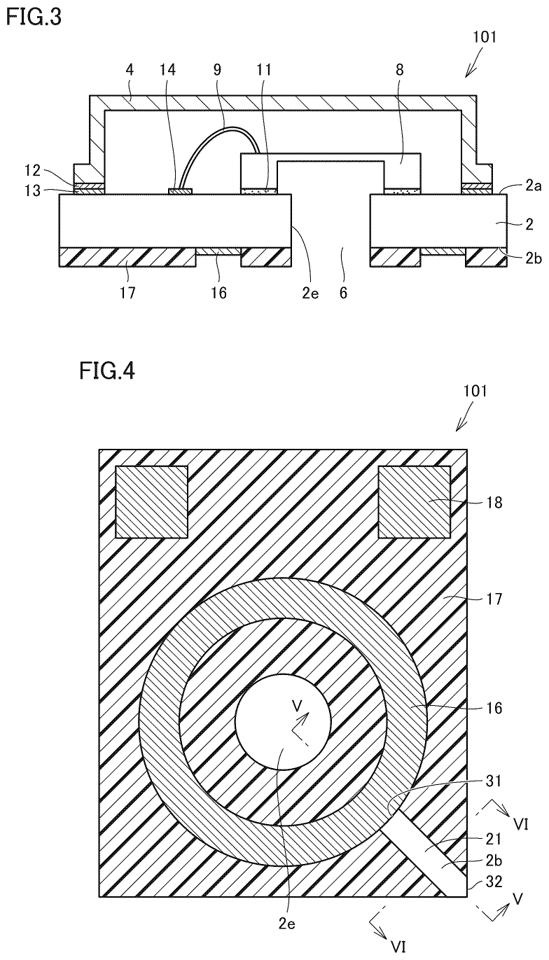

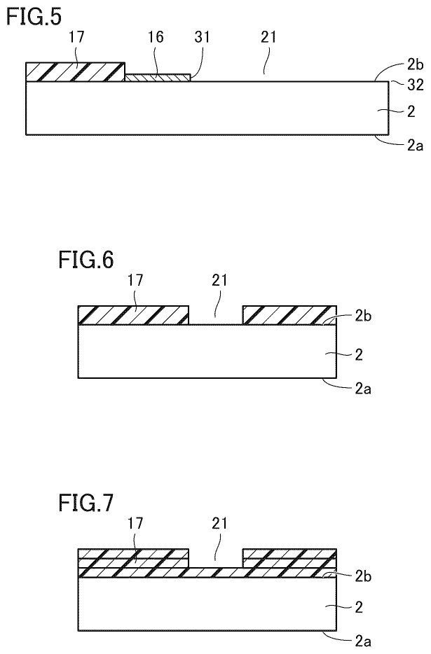

An acoustic device according to a first example embodiment of the present invention will be described with reference to FIGS. 1 to 7. FIG. 1 shows an appearance of an acoustic device 101 in the present example embodiment. Acoustic device 101 includes a substrate 2 and a lid portion 4. FIG. 2 shows an exploded view of acoustic device 101. FIG. 3 shows a cross-sectional view along the line III-III in FIG. 1. FIG. 4 show a bottom view of acoustic device 101. FIG. 5 shows a cross-sectional view along the line V-V in FIG. 4. FIG. 6 shows a cross-sectional view along the line VI-VI in FIG. 4.

Acoustic device 101 includes substrate 2, an acoustic MEMS element 8, an annular electrode 16, and a solder resist layer 17. Substrate 2 includes a first surface 2a and a second surface 2b that faces a side opposite to first surface 2a. Substrate 2 includes an opening 2e. Opening 2e is a through hole. Acoustic MEMS element 8 is fixed to first surface 2a to cover opening 2e. Acoustic MEMS element 8 is fixed to first surface 2a of substrate 2 with a die bonding agent 11. Die bonding agent 11 is a thermosetting adhesive. Acoustic MEMS element 8 includes a membrane portion. A region of acoustic MEMS element 8 surrounded by a dashed line in FIG. 2 is the membrane portion. As shown in FIG. 3, port 6 is defined by opening 2e. Port 6 is an inlet or an outlet for sound. For example, some kind of barrier to achieve waterproofing, dustproofing, or the like may be provided in port 6. In an example where port 6 serves as the inlet for sound, sound enters the inside of acoustic device 101 through port 6 to vibrate the membrane portion of acoustic MEMS element 8. In an example where port 6 serves as the outlet of sound, sound is generated by vibration of the membrane portion of acoustic MEMS element 8 and this sound goes out of acoustic device 101 through port 6.

As shown in FIG. 2, two electrodes 14 are aligned at appropriate positions on first surface 2a. An upper surface of acoustic MEMS element 8 is electrically connected to electrodes 14 through wires 9. In other words, acoustic MEMS element 8 is wire-bonded to electrodes 14. An electrode 13 is arranged in a form of a frame in the vicinity of an outer edge of first surface 2a. Lid portion 4 is connected to electrode 13 with a conductive adhesive 12 being interposed. Conductive adhesive 12 is thermosetting. Lid portion 4 covers and hides acoustic MEMS element 8, wires 9, electrodes 14, and the like. Lid portion 4 is formed of a conductive material. Lid portion 4 is formed, for example, of metal.

As shown in FIG. 4, annular electrode 16 is arranged to surround opening 2e on second surface 2b. Annular electrode 16 is electrically connected to lid portion 4 through a copper foil on first surface 2a, electrode 13, and conductive adhesive 12. Solder resist layer 17 is arranged to cover second surface 2b adjacently to annular electrode 16 on an outer side and an inner side of annular electrode 16. Solder resist layer 17 includes a first cutaway portion 21 to connect a first portion 31 which is any portion in an edge of annular electrode 16 and a second portion 32 which is any portion in an edge of substrate 2 to each other. In the present example embodiment, by way of example, first portion 31 is a portion of an outer edge of annular electrode 16 and second portion 32 is a portion of an outer edge of substrate 2. Annular electrode 16 may be in a circularly surrounding shape as shown in FIG. 4 or in a surrounding shape other than the circular shape.

As shown in FIG. 4, a pad electrode 18 is provided on second surface 2b on the outer side of annular electrode 16. By way of example, two pad electrodes 18 are provided. The number of pad electrodes 18 may be other than two. Pad electrode 18 is electrically connected to acoustic MEMS element 8 through electrodes 14 and wires 9.

In the present example embodiment, as shown in FIGS. 4 to 6, first cutaway portion 21 is a region where solder resist layer 17 is absent. First cutaway portion 21 is in a state in which a material to be wetted with solder such as a copper foil is not exposed at a surface. In first cutaway portion 21, second surface 2b of substrate 2 is exposed. Alternatively, in a modification, as shown in FIG. 7, a structure may be such that solder resist layer 17 includes a plurality of layers and the number of layers is small in first cutaway portion 21 to provide a recess. Alternatively, the structure may be such that solder resist layer 17 is in a single-layered structure and recessed in first cutaway portion 21. First cutaway portion 21 should only be a passage through which an outgas generated from solder can pass, by being present as a region where solder resist layer 17 locally does not cover the substrate or being present as a region where solder resist layer 17 is recessed.

Solder resist layer 17 includes first cutaway portion 21 in the present example embodiment. Therefore, even when an outgas is generated from solder attached to annular electrode 16 or the mount substrate in the reflow step in mounting acoustic device 101 by soldering, an outgas can escape through first cutaway portion 21. Therefore, a probability that an outgas is confined in solder to become a void can be reduced or prevented. In other words, according to the present example embodiment, the acoustic device in which a void in solder is less likely to occur during solder mounting with the use of the annular electrode surrounding the port can be obtained. The reduced likeliness of a void in solder means that annular electrode 16 may be reduced in size, which consequently leads to a reduction in size of the acoustic device as a whole.

Though FIG. 2 shows the exploded view of a single acoustic device 101, in production of acoustic devices 101, a structure corresponding to a plurality of acoustic devices 101 may be constructed on a surface of a large substrate and individual acoustic devices 101 may then be obtained by dicing this substrate.

### Second Example Embodiment

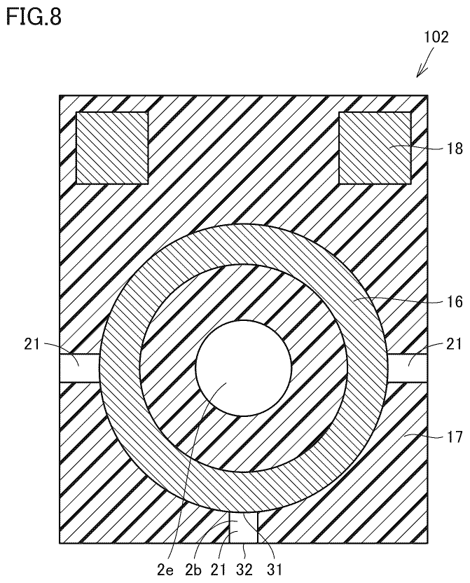

An acoustic device according to a second example embodiment of the present invention will be described with reference to FIG. 8. FIG. 8 shows a bottom view of an acoustic device 102 in the present example embodiment. Acoustic device 102 includes first cutaway portion 21 at a position where a distance between first portion 31 and second portion 32 is shortest. As shown in FIG. 8, acoustic device 102 includes a plurality of first cutaway portions 21. By way of example, three first cutaway portions 21 are provided. The position at which the distance between first portion 31 and second portion 32 is shortest refers to a position where a distance between annular electrode 16 and a lower side is shortest in FIG. 8, and first cutaway portion 21 is provided at least at this position. Since the construction of other portions is similar to that in acoustic device 101 described in the first example embodiment, description will not be repeated.

The present example embodiment can also obtain the advantageous described in the first example embodiment. Furthermore, since first cutaway portion 21 is provided at the position where the distance between first portion 31 and second portion 32 is shortest in the present example embodiment, a length of a path through which an outgas passes to escape is short. Therefore, the outgas can efficiently escape.

In the example shown in FIG. 8, in the whole device, the distance between annular electrode 16 and a side is shortest in the lower side. In another side as well, first cutaway portion 21 is provided at a position in that side where the distance from annular electrode 16 is shortest. Thus, first cutaway portion 21 is provided preferably at the position where the distance is locally shortest even though the distance is not necessarily shortest in the whole device.

As shown in the present example embodiment, preferably, a plurality of first cutaway portions 21 are provided in second surface 2b and the plurality of first cutaway portions 21 are symmetrically positioned. By adopting this construction, warpage of substrate 2 due to thermal stress in thermal curing of die bonding agent 11, conductive adhesive 12, or the like can be reduced or prevented.

### Third Example Embodiment

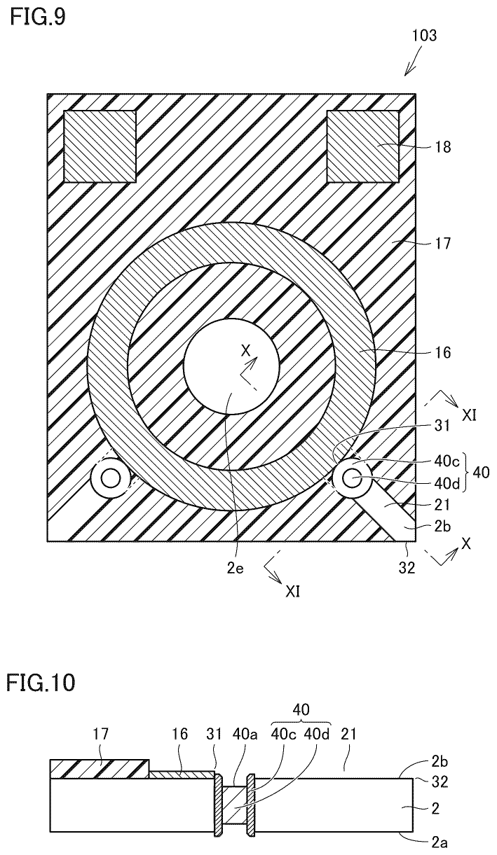

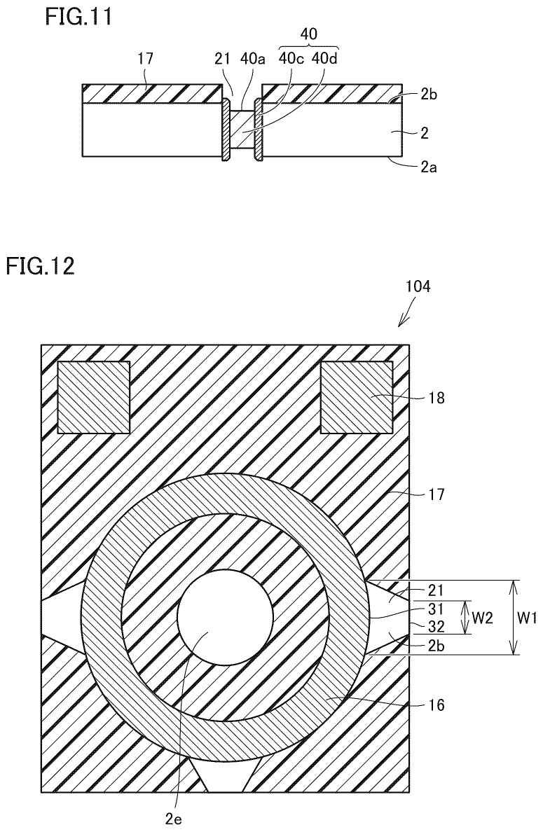

An acoustic device according to a third example embodiment of the present invention will be described with reference to FIGS. 9 to 11. FIG. 9 shows a bottom view of an acoustic device 103 in the present example embodiment. FIG. 10 shows a cross-sectional view along the line X-X in FIG. 9. FIG. 11 shows a cross-sectional view along the line XI-XI in FIG. 9. Acoustic device 103 includes a conductor via 40 that passes through substrate 2 to electrically connect a side of first surface 2a and a side of second surface 2b to each other. As shown in FIGS. 10 and 11, a via exposed portion 40a which is a portion where conductor via 40 is exposed on the side of second surface 2b includes a portion lower than second surface 2b. Via exposed portion 40a is a part of first cutaway portion 21. Annular electrode 16 more specifically includes a copper foil and a plated film that covers an upper surface thereof. The copper foil that is a portion of annular electrode 16 extends toward conductor via 40 over a certain width at a portion where conductor via 40 is present. An outer geometry of this extending portion of the copper foil is shown in the vicinity of conductor via 40 with a dashed line in FIG. 9.

Though two conductor vias 40 are provided in the example shown in FIG. 9, a single conductor via 40 or three or more conductor vias 40 may be provided. Conductor via 40 exemplified here includes a cylindrical first portion 40c and a second portion 40d that fills a portion of an internal space in first portion 40c. Via exposed portion 40a is lower than second surface 2b in second portion 40d. The shape of conductor via 40 shown here is merely by way of example. Actually, conductor via 40 may be in a form of a hollow cylinder including only first portion 40c without including second portion 40d. Conductor via 40 may be constructed in such a manner that the inside of a cylinder is filled with resin, a conductive material, or the like as illustrated. Since the construction of other portions is similar to that in acoustic device 101 described in the first example embodiment, description will not be repeated.

The present example embodiment can also obtain the advantageous described in the first example embodiment. Furthermore, since via exposed portion 40a which is the portion where conductor via 40 is exposed on the side of second surface 2b is recessed relative to second surface 2b in the present example embodiment, an outgas generated from solder can be guided to via exposed portion 40a in the reflow step. Since the outgas can be guided to via exposed portion 40a and thereafter can escape through first cutaway portion 21, the outgas can efficiently be exhausted.

### Fourth Example Embodiment

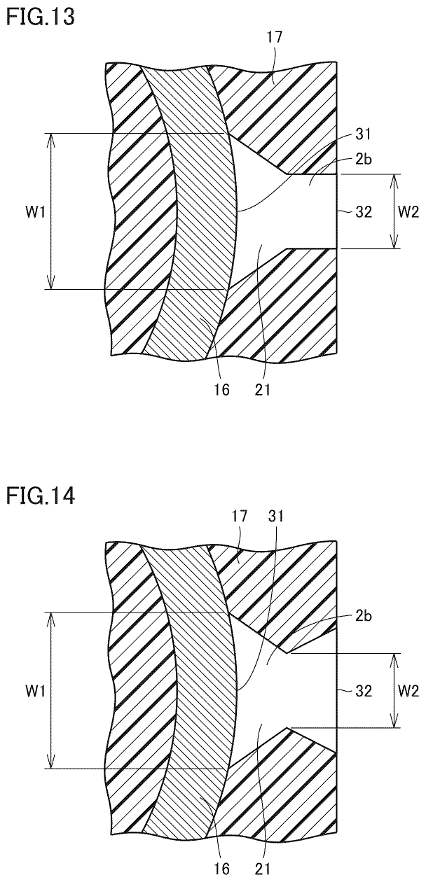

An acoustic device according to a fourth example embodiment of the present invention will be described with reference to FIG. 12. FIG. 12 shows a bottom view of an acoustic device 104 in the present example embodiment. In acoustic device 104, first cutaway portion 21 has a first width W1 in first portion 31, first width W1 being the largest width, and has a second width W2 in any portion other than first portion 31, second width W2 being narrower than first width W1. Specifically, first cutaway portion 21 has the largest width on a side where it is in contact with annular electrode 16, and it is narrower in portions other than that. In the example shown in FIG. 12, first cutaway portion 21 is narrowest in width in a portion where it is in contact with the outer edge of substrate 2. Since the construction of other portions is similar to that in acoustic device 101 described in the first example embodiment, description will not be repeated.

The present example embodiment can also obtain the advantageous described in the first example embodiment. Furthermore, since a cross-sectional area over which annular electrode 16 and first cutaway portion 21 are in contact is large in the present example embodiment, an outgas generated from solder arranged on annular electrode 16 can efficiently escape. As shown in the present example embodiment, when the width of first cutaway portion 21 is narrow at the portion where it is in contact with the outer edge of substrate 2, entry of particles, corrosive gas, or the like from an outer periphery of acoustic device 104 into first cutaway portion 21 can be reduced or prevented.

Though an example in which first cutaway portion 21 has the narrowest width in the portion where it is in contact with the outer edge of substrate 2 is shown in the present example embodiment, the portion where first cutaway portion 21 is narrow in width is not limited to the portion where it is in contact with the outer edge of substrate 2. For example, a construction as shown in FIG. 13 may be applicable. In this example, first cutaway portion 21 has first width W1 at first portion 31, and gradually decreases in width with distance from first portion 31 and has a constant width from an intermediate point. This constant width is second width W2. First cutaway portion 21 reaches the outer edge of substrate 2 with the constant width being maintained. In other words, first cutaway portion 21 includes a tapered portion and a straight portion.

Alternatively, a construction as shown in FIG. 14 may be applicable. In this example, first cutaway portion 21 has first width W1 at first portion 31, and initially gradually decreases in width with distance from first portion 31, and from the intermediate point, gradually increases in width to the contrary. The width of the narrowest portion in the middle is second width W2. Therefore, first cutaway portion 21 is in a shape with the narrowest portion in the middle. In other words, first cutaway portion 21 is constricted in the middle.

Second width W2 is not necessarily the narrowest width. A portion having second width W2 as some width narrower than first width W1 should only be present at any portion in first cutaway portion 21.

### Fifth Example Embodiment

An acoustic device according to a fifth example embodiment of the present invention will be described with reference to FIG. 15. FIG. 15 shows a bottom view of an acoustic device 105 in the present example embodiment. In acoustic device 105, first portion 31 is a portion of an inner edge of annular electrode 16 and second portion 32 is a portion of an edge of opening 2e. In acoustic device 105 again, first cutaway portion 21 has first width W1 at first portion 31, first width W1 being the largest width, and has second width W2 at any portion other than first portion 31, second width W2 being narrower than first width W1. Since the construction of other portions is similar to that in acoustic device 101 described in the first example embodiment, description will not be repeated.

The present example embodiment can also obtain the advantageous described in the first example embodiment. In the present example embodiment, since first cutaway portion 21 does not communicate with an outer edge portion, dicing chips resulting from dicing of substrate 2 do not adhere to or remain in first cutaway portion 21. Therefore, there is no possibility that dicing chips that adhere or remain move in a subsequent step and adhere again to annular electrode 16 to cause defective mounting, or that dicing chips come in through opening 2e toward first surface 2a to cause break of acoustic MEMS element 8 or variation in characteristics. When there is a concern about such a defect caused by dicing chips in a conventional example, a cleaning step is performed after a dicing step. In this case, however, acoustic MEMS element 8 may be broken due to the cleaning step. In the present example embodiment, there is no possibility that dicing chips adhere to or remain in first cutaway portion 21, and hence the cleaning step does not have to be performed and break of acoustic MEMS element 8 can be prevented. Therefore, an assembly step can also be simplified.

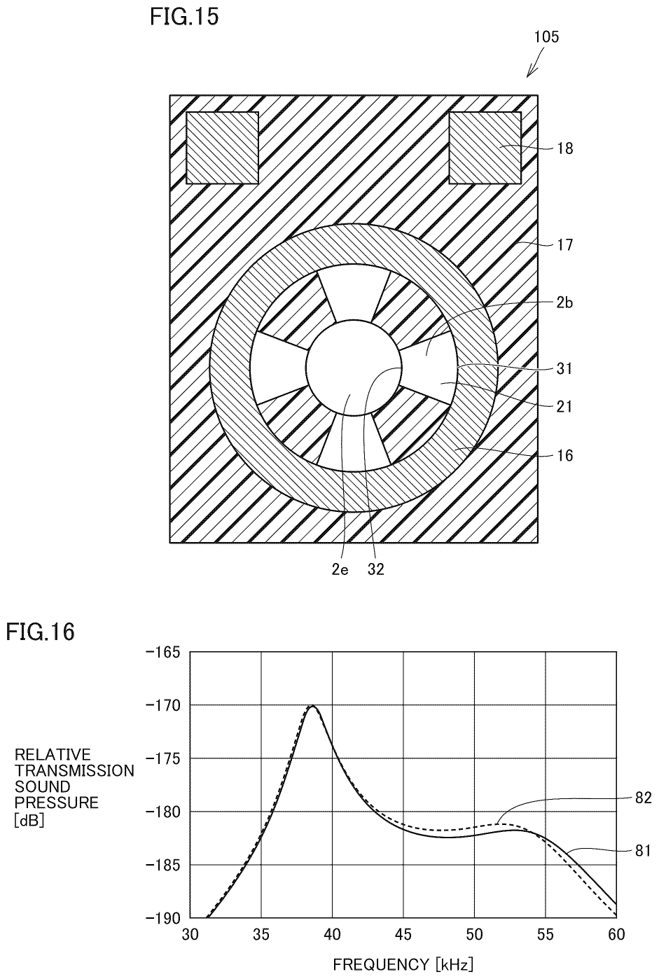

FIG. 16 shows a graph obtained by studies about relation between a frequency and a sound pressure. A curve 81 represents relation when first cutaway portion 21 is not provided. A curve 82 represents relation when first cutaway portion 21 is provided. As is clear from FIG. 16, as first cutaway portion 21 is provided, a peak of a sound pressure can be broader in band with respect to the frequency. In particular, when the present example embodiment is applied to the MUT, a peak of the sound pressure in transmission of ultrasonic waves can be broader in band with respect to the frequency.

Though an example in which the width of first cutaway portion 21 provided on the inner side of annular electrode 16 gradually decreases with distance from annular electrode 16 is shown, first cutaway portion 21 may have a constant width. A manner of variation in width of first cutaway portion 21 may be any manner of variation other than a tapered manner or a straight manner.

### Sixth Example Embodiment

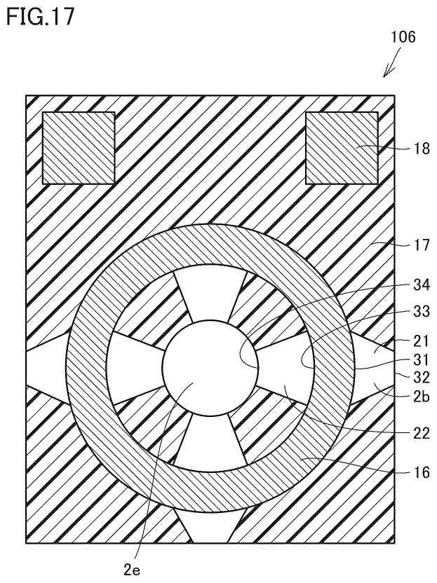

An acoustic device according to a sixth example embodiment of the present invention will be described with reference to FIG. 17. FIG. 17 shows a bottom view of an acoustic device 106 in the present example embodiment. The present example embodiment corresponds to combination of the fourth and fifth example embodiments.

In acoustic device 106, solder resist layer 17 includes first cutaway portion 21 to connect first portion 31 which is any portion in the outer edge of annular electrode 16 and second portion 32 which is any portion in the outer edge of substrate 2 to each other. Furthermore, in acoustic device 106, solder resist layer 17 includes a second cutaway portion 22 which is a passage through which gas can pass to connect a third portion 33 which is any portion in an inner edge of annular electrode 16 and a fourth portion 34 which is any portion in an edge of opening 2e to each other. In other words, the cutaway portion in solder resist layer 17 is provided on each of the inner side and the outer side of annular electrode 16.

Since solder resist layer 17 includes the cutaway portion on each of the outer side and the inner side of annular electrode 16 in the present example embodiment, an outgas generated from solder can efficiently escape through the cutaway portions.

### Seventh Example Embodiment

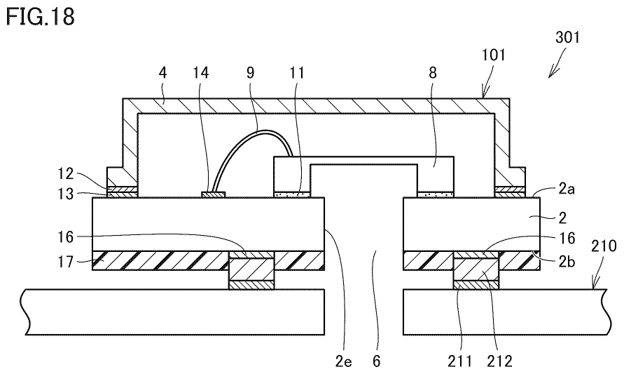

A module according to a seventh example embodiment of the present invention will be described with reference to FIG. 18. FIG. 18 shows a cross-sectional view of a module 301 in the present example embodiment.

Module 301 in the present example embodiment includes acoustic device 101 described in the first example embodiment and a mount substrate 210 provided with a connection electrode 211 on a surface thereof. Acoustic device 101 is mounted on mount substrate 210 while annular electrode 16 and connection electrode 211 are electrically connected to each other with solder 212 being interposed. Mount substrate 210 includes an opening. Acoustic device 101 is arranged such that opening 2e in substrate 2 is located at a position corresponding to the opening in mount substrate 210. Though not shown in FIG. 18, mount substrate 210 includes a pad electrode to be connected to pad electrode 18, also at a position corresponding to pad electrode 18. Pad electrode 18 of acoustic device 101 is connected to the corresponding pad electrode of mount substrate 210 with solder being interposed.

Even when an outgas is generated from solder 212 or mount substrate 210 in the reflow step in mounting acoustic device 101 with the use of solder 212 in the present example embodiment, an outgas can escape through first cutaway portion 21. Therefore, a probability that an outgas is confined in solder 212 to become a void can be lowered. In other words, a module in which a void in solder is less likely in solder mount with the use of the annular electrode arranged to surround the port can be obtained.

Though an example in which module 301 includes acoustic device 101 is illustrated and described, the acoustic device described in any example embodiment above may be provided instead of acoustic device 101.

A plurality of example embodiments of the example embodiments above may be adopted as being combined as appropriate.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic device comprising:
a substrate including a first surface and a second surface that faces a side opposite to the first surface, the substrate being provided with an opening;
an acoustic MEMS element fixed to the first surface to cover the opening;
an annular electrode surrounding the opening on the second surface; and
a solder resist layer covering the second surface adjacently to the annular electrode on an outer side and an inner side of the annular electrode; wherein
the solder resist layer includes a first cutaway portion to connect a first portion and a second portion to each other, the first portion being any portion in an edge of the annular electrode, the second portion being any portion in an edge of the substrate.

2. The acoustic device according to claim 1, wherein the first portion is a portion of an outer edge of the annular electrode and the second portion is a portion of an outer edge of the substrate.

3. The acoustic device according to claim 1, wherein the first portion is a portion of an inner edge of the annular electrode and the second portion is a portion of an edge of the opening.

4. The acoustic device according to claim 2, wherein the first cutaway portion is provided at a position where a distance between the first portion and the second portion is shortest.

5. The acoustic device according to claim 1, wherein the first cutaway portion has a first width at the first portion, the first width being a largest width, and has a second width at any portion other than the first portion, the second width being narrower than the first width.

6. The acoustic device according to claim 1, further comprising a conductor via extending through the substrate to electrically connect a first surface side and a second surface side to each other; wherein
a via exposed portion which is a portion where the conductor via is exposed to the second surface side includes a portion lower than the second surface; and
the via exposed portion is a portion of the first cutaway portion.

7. The acoustic device according to claim 1, wherein a plurality of first cutaway portions are located in the second surface, and the plurality of first cutaway portions are symmetrically arranged.

8. The acoustic device according to claim 2, wherein the solder resist layer includes a second cutaway portion to connect a third portion and a fourth portion to each other, the second cutaway portion being a passage through which gas can pass, the third portion being any portion in an inner edge of the annular electrode, the fourth portion being any portion in an edge of the opening.

9. The acoustic device according to claim 1, wherein the opening is a through hole.

10. The acoustic device according to claim 1, wherein the opening defines a port for sound.

11. A module comprising:
the acoustic device according to claim 1; and
a mount substrate provided with a connection electrode on a surface; wherein
the acoustic device is mounted on the mount substrate and the annular electrode and the connection electrode are electrically connected to each other via solder interposed therebetween.

12. The module according to claim 11, wherein the first portion is a portion of an outer edge of the annular electrode and the second portion is a portion of an outer edge of the substrate.

13. The module according to claim 11, wherein the first portion is a portion of an inner edge of the annular electrode and the second portion is a portion of an edge of the opening.

14. The module according to claim 12, wherein the first cutaway portion is provided at a position where a distance between the first portion and the second portion is shortest.

15. The module according to claim 11, wherein the first cutaway portion has a first width at the first portion, the first width being a largest width, and has a second width at any portion other than the first portion, the second width being narrower than the first width.

16. The module according to claim 11, further comprising a conductor via extending through the substrate to electrically connect a first surface side and a second surface side to each other; wherein
a via exposed portion which is a portion where the conductor via is exposed to the second surface side includes a portion lower than the second surface; and
the via exposed portion is a portion of the first cutaway portion.

17. The module according to claim 11, wherein a plurality of first cutaway portions are located in the second surface, and the plurality of first cutaway portions are symmetrically arranged.

18. The module according to claim 12, wherein the solder resist layer includes a second cutaway portion to connect a third portion and a fourth portion to each other, the second cutaway portion being a passage through which gas can pass, the third portion being any portion in an inner edge of the annular electrode, the fourth portion being any portion in an edge of the opening.

19. The module according to claim 11, wherein the opening is a through hole.

20. The module according to claim 11, wherein the opening defines a port for sound.
